(19) United States
(12) Patent Application Publication
(10) Pub. No.: US 2010/0292942 A1
(43) Pub. Date: Nov. 18, 2010

(54) Embedded algorithms for vehicular batteries

(76) Inventors: Lonnie Calvin Golf, Tempe, AZ (US); Michael Richard Conley, Thousand Oaks, CA (US); Mark E. Eidson, Tempe, AZ (US)

Correspondence Address: Lonnie Golf, 1433 S. Mill Ave., Tempe, AZ, 85281, US

(21) Appl. No.: 12/454,454

(22) Filed: May 18, 2009

(51) Int. Cl. G01R 31/36

(52) U.S. Cl. 702/63; 324/427

(57) ABSTRACT

Computer algorithms design to execute on a computer system embedded inside a starter or deep cycle battery that calculate optimal charge rates and detect internal alarm conditions and make this information externally available.

### CROSS REFERENCE TO RELATED APPLICATIONS

This application is related to the following applications that have all been filed by the present inventors. Ser. No. 12/075,212 filed on Mar. 10, 2008 and entitled “Battery Monitor System Attached to a Vehicle Wiring Harness”. Ser. No. 12/070,793 filed on Feb. 20, 2008 and entitled “Multi-function Battery Monitor System for Vehicles”. Ser. No. 12/319,544 filed on Jan. 8, 2009 and entitled “Battery Monitoring Algorithms for Vehicles”. Ser. No. 12/321,310 filed on Jan. 15, 2009 and entitled “Embedded Monitoring System for Batteries”. And Ser. No. 12/380,236 filed on Feb. 25, 2009 and entitled “Embedded Microprocessor System for Vehicular Batteries”.

This application expands the battery monitoring functions defined in Ser. No. 12/321,310 “Embedded Monitoring System for Batteries” and Ser. No. 12/380,236 “Embedded Microprocessor System for Vehicular Batteries” by the present inventors to include embedded algorithmic processing of the monitored data.

### FEDERALLY SPONSORED RESEARCH OR DEVELOPMENT

Not Applicable

### SEQUENCE LISTING, TABLE OR COMPUTER PROGRAM LISTING ON CD

Not Applicable

### BACKGROUND OF THE INVENTION

1. Field of Invention

The present invention relates to the field of computers. In particular it relates to computer based methods for calculating important information about the internal state of starter and deep cycle power batteries and making these calculations available externally.

2. Prior Art

All batteries fail. The life expectancy of an automobile battery ranges from 30 months in southern Arizona to 51 months in Alaska. In 2008, the number of automobile, truck, motorcycle, marine and deep cycle batteries sold in the US was approximately 98 million units. This represents an annual replacement cost to the American consumer of over 6 billion dollars. In addition to the upfront consumer cost associated with battery replacement there is both energy and environmental costs associated with the recycling of dead batteries. There is a cost in non-renewable fossil fuel to transport millions of batteries to recycle centers. There is an additional energy cost required to pulverize battery cases and finally there is a very large energy cost associated with smelting the lead and various other separable materials. Lastly, assuming 97% of all batteries get recycled, there still remain approximately 3 million units full of toxic lead and caustic acid that are dumped in the environment every year.

The single most prevalent cause of the premature failure of starting batteries, deep cycle motive batteries and stationary deep cycle batteries is incorrect battery charging. Overcharging causes grid corrosion. Undercharging causes battery sulfation. Both lead to premature battery failure.

Charging systems included in today's automobiles are, at best, crude instruments for they lack information relating to the internal state of the battery. The best alternator systems use, at best, only the temperature on the outside of the battery case. The type of battery being charged as well as its internal temperature, internal pressure, charge state and, if applicable, electrolyte level and specific gravity are all unknown. Different battery types require different charging voltages. An Absorbed Glass Mat battery should be charged at 14.3 volts when the temperature of the battery is 80 degrees Fahrenheit. A flooded Maintenance Free battery should be charged at 14.8 volts for the same temperature. If the level of the electrolyte does not completely cover all plates, no charging should be performed and the operator of the vehicle should be warned. If the specific gravity reading has dropped sufficiently a carefully monitored higher than normal equalization charge should be applied to the battery. If the temperature of the battery spikes or the internal pressure of the battery becomes excessive all charging should stop in order to prevent thermal runaway or excessive loss of electrolyte.

None of today's vehicular batteries provide the information required by charging systems to perform optimal charging. Optimal charging which will in turn eliminate the most prevalent of premature battery failures as well as enhance the normal life expectancy of vehicular and deep cycle batteries.

### BRIEF SUMMARY OF THE INVENTION

The present invention makes use of a computer system that is described in both Ser. No. 12/321,310 filed on Jan. 15, 2009 and entitled “Embedded Monitoring System for Batteries” and Ser. No. 12/380,236 filed on Feb. 25, 2009 and entitled “Embedded Microprocessor System for Vehicular Batteries”. This computer is designed to reside inside the case of a starter or deep cycle battery. The computer system described in these two previous applications makes use of one or more of the battery's cells as its power source or includes provisions for a separate power source. The computer system includes some combination of zero, one or more sensors that measure internal battery temperature, internal battery pressure, internal current, level of liquid electrolyte, internal voltage and specific gravity. The computer system includes algorithms that render the optimal charging voltage or charging current for the battery based upon its internal sensor data. The computer system includes algorithms that detect battery alarm conditions based upon its internal sensor data. The computer system also includes an electrical interface that can transfer information to locations external to the battery.

Per one embodiment, the computer system includes a temperature sensor, a voltage sensor, a current sensor and liquid level sensors installed in each battery cell. The computer system monitors its sensors and from this information calculates optimal charge and alarm conditions and transmits this information over a wired bus using an automotive industry standard protocol such as the CAN-Bus (Controller Area Network).

Per another embodiment, the computer system includes a pressure sensor, a temperature sensor and a voltage sensor. The computer system monitors its sensors and from this information calculates optimal charge and alarm conditions and transmits this information over the battery's power cable by using an automotive industry standard protocol such as the LIN-Bus (Local Interconnect Network).

### BRIEF DESCRIPTION OF THE DRAWINGS

FIG. 1 is a block diagram of a computer-based system shown embedded inside an unsealed automotive battery. This system includes means for measuring the level of the electrolyte in each cell and includes means for measuring battery temperature, battery voltage and battery current. The computer system includes algorithms with means for rendering optimal battery charge rates from the sensory data. The computer system includes algorithms with means for recognizing internal battery alarm conditions based upon the sensory data. The computer system includes means for communicating optimal charge rate and alarm information across a wired communication channel.

FIG. 1A is a flow chart illustrating the steps taken by the computer system of FIG. 1 to make available optimal battery charge rates and internal battery alarms to an external device.

FIG. 2 is a block diagram of a computer-based system shown embedded inside a sealed automotive battery. This system includes means for measuring battery pressure, temperature and voltage. The computer system includes algorithms with means for rendering optimal battery charge rates from the sensory data. The computer system includes algorithms with means for recognizing internal battery alarm conditions based upon the sensory data. The computer system includes means for communicating optimal charge rate and alarm information across the power cable attached to the battery terminal.

FIG. 2A is a flow chart illustrating the steps taken by the computer system of FIG. 2 to make available optimal battery charge rates and internal battery alarms to an external device.

### DETAILED DESCRIPTION OF THE INVENTION

The following descriptions are provided to enable any person skilled in the art to make and use the invention and is provided in the context of two particular embodiments. Various modifications to these embodiments are possible and the generic principles defined herein may be applied to this and other embodiments without departing from the spirit and scope of the invention. Special notification is made with regard to deep-cycle motive and non-motive batteries. The generic principles defined herein apply to these batteries. Thus the invention is not intended to be limited to the embodiments shown but is to be accorded the widest scope consistent with the principles, features and teachings disclosed herein.

In accordance with one embodiment, the present invention makes use of a computer system that resides inside an unsealed automotive battery's case and communicates to the outside world through a communication connector installed in the battery's case. The computer system includes one temperature sensor, one voltage sensor, one current sensor and one liquid level sensor installed in each battery cell. The computer system's central processing unit also has the ability to measure time and includes facilities for storing data. The computer system's non-volatile memory includes algorithms that calculate optimal charge rates based upon its sensor information and based upon manufacturing information that relates to the battery's construction and charging characteristics. The computer system's non-volatile memory includes algorithms that detect battery alarm conditions using information read from the sensors.

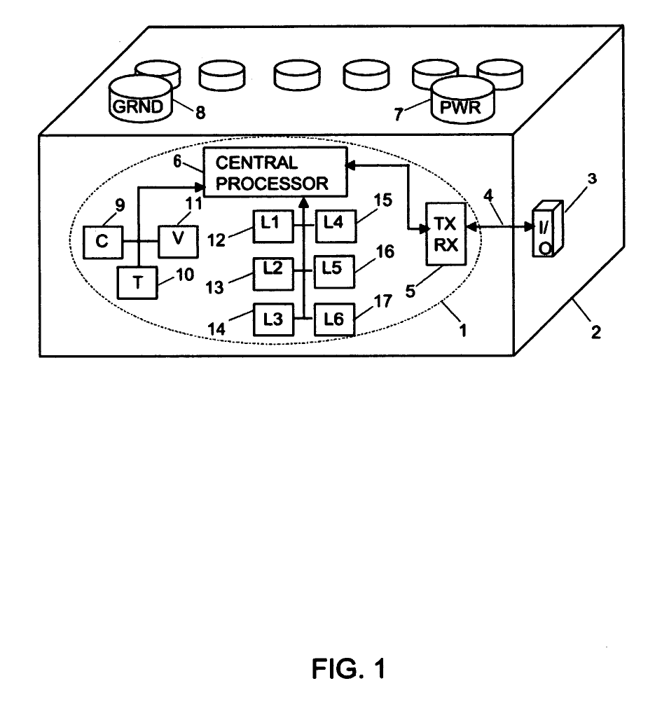

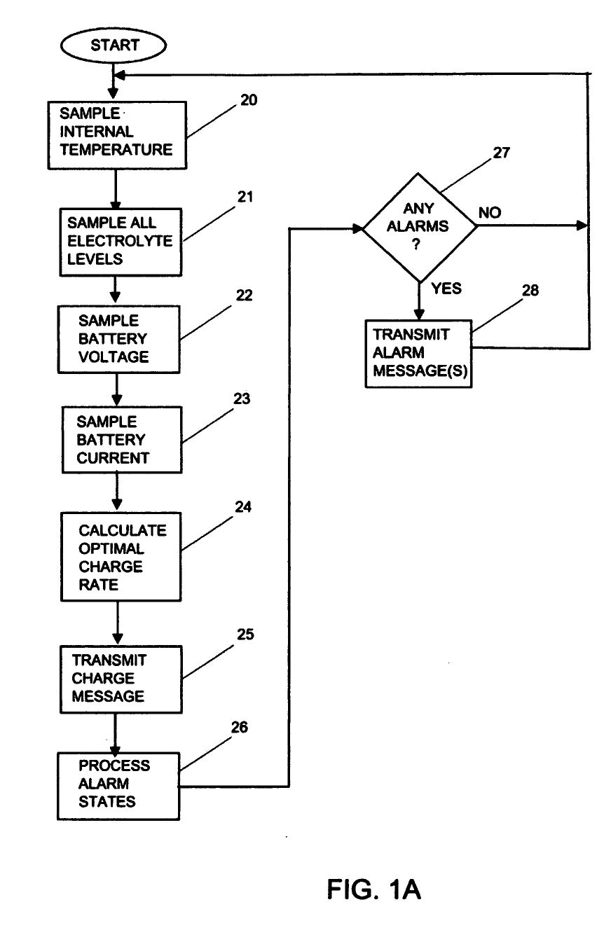

FIG. 1 is a block diagram illustrating computer system I shown embedded inside battery 2. Computer system 1 includes a data path to communication connector 3 through conductor 4. Transceiver 5 is used to transfer information between central processor 6 and one or more external devices (not shown) attached to connector 3 using the industry standard Controller Area Network vehicle bus protocol. Current sensor 9 measures battery current. Temperature sensor 10 measures the temperature inside the battery's case. Voltage sensor 11 internally measures the voltage drop between the two battery posts 7 and 8 (the connection between this sensor and the two battery posts not shown). Sensors 12-17 provide the level of the electrolyte in all of the battery's cells. Central processor 6 includes in its non-volatile memory manufacturing information. Central processor 6 uses transceiver 5 to monitor data activity on input/output connector 3.

FIG. 1A is a flowchart illustrating those steps taken by computer system 1 in FIG. 1 in order to calculate the required charge rate, detect alarm conditions and make this information available to an external device. In step 20 of FIG. 1A the battery temperature sensor 10 of FIG. 1 is sampled by central processor 6 of FIG. 1 and saved. At step 21 of FIG. 1A level sensors 12, 13, 14, 15, 16 and 17 in FIG. 1 are sampled by central processor 6 in FIG. 1 and saved. At step 22 of FIG. 1A voltage sensor 11 of FIG. 1 is sampled by central processor 6 of FIG. 1 and saved. At step 23 of FIG. 1A current sensor 9 of FIG. 1 is sampled by central processor 6 of FIG. 1 and saved. At step 24 central processor 6 of FIG. 1 calculates the optimal charge that should be externally applied to the battery based upon its sensor information and based upon its manufacturing information as it relates to the battery's construction and charging characteristics. At step 25 of FIG. 1A a message containing the charge rate and current state of charge of the battery is transmitted to an external device (not shown) using transceiver 5 and connector 3 of FIG. 1. At step 26 the sensor readings taken in steps 20-23 are examined by central processor 6 of FIG. 1 in order to ascertain the presence of alarm conditions. If one or more alarm conditions exist, step 27 passes program control to step 28 where the alarm information is transmitted to an external device (not shown) using transceiver 5 and connector 3 of FIG. 1. Program control then proceeds to step 20. The flowchart repeats.

In accordance with another embodiment, the present invention makes use of a computer system that resides inside a sealed battery's case and communicates to the outside world through the power cable attached to the battery's power terminal. The computer system includes one temperature, one voltage and one pressure sensor. The computer system's central processing unit also has the ability to measure time and includes facilities for storing data. The computer system's non-volatile memory includes algorithms that calculate optimal charge rates based upon its sensor information and based upon manufacturing information that relates to the battery's construction and charging characteristics. The computer system's non-volatile memory includes algorithms that detect battery alarm conditions using information read from the sensors.

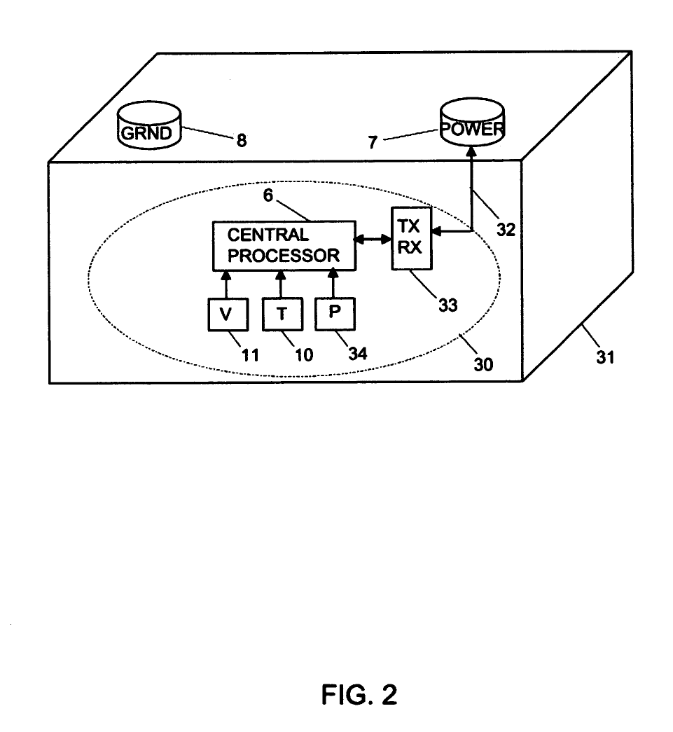

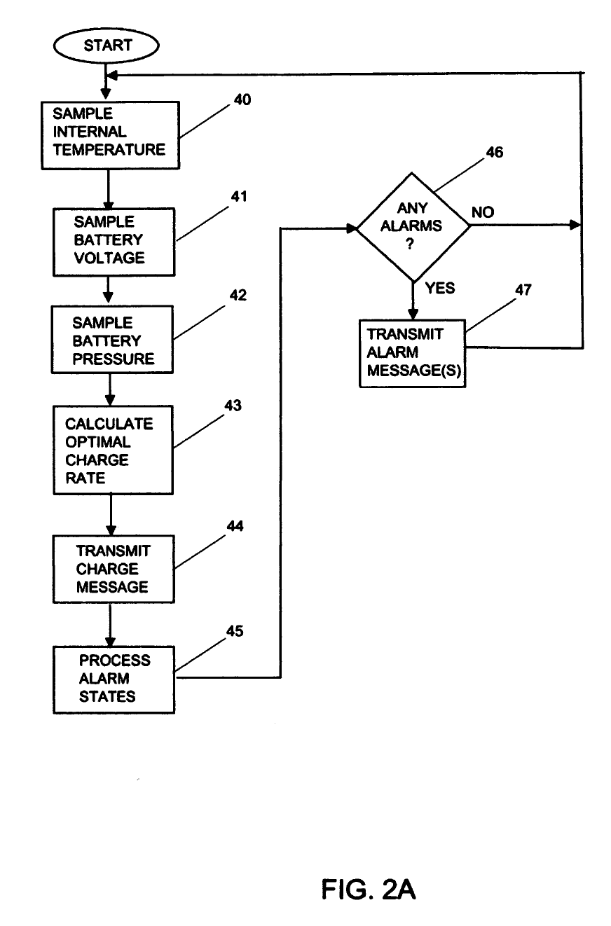

FIG. 2 is a block diagram illustrating computer system 30 shown embedded inside battery 31. Computer system 30 includes an electrical connection to battery terminal 7 through conductor 32. Transceiver 33 makes use of conductor 32 to transfer digital data over the battery power cable between central processor 6 and one or more devices (not shown) externally attached to the terminal 7 power cable. Voltage sensor 11 internally measures the voltage drop between battery posts 7 and 8 (the connection between this sensor and the two battery posts not shown). Temperature sensor 10 measures the temperature inside the battery's case. Pressure sensor 34 measures the pressure inside the sealed battery's case. Central processor 6 includes in its non-volatile memory battery manufacturing information. Central processor 6 uses transceiver 33 to monitor data activity, which may be present on battery post 7.

FIG. 2A is a flowchart illustrating those steps taken by computer system 30 in FIG. 2 in order to calculate the required charge rate, detect alarm conditions and make this information available to an external device. In step 40 of FIG. 2A the battery temperature sensor 10 of FIG. 2 is sampled by central processor 6 of FIG. 2 and saved. At step 41 of FIG. 2A voltage sensor 11 of FIG. 2 is sampled by central processor 6 of FIG. 2 and saved. At step 42 of FIG. 2A pressure sensor 34 of FIG. 2 is sampled by central processor 6 of FIG. 2 and saved. At step 43 central processor 6 of FIG. 2 calculates the optimal charge that should be externally applied to the battery based upon its sensor information and based upon its manufacturing information as it relates to the battery's construction and charging characteristics. At step 44 of FIG. 2A a message containing the calculated charge rate and current state of charge of the battery is transmitted to an external device (not shown) using transceiver 33, conductor 32 and power connector 7 of FIG. 2. At step 45 the sensor readings taken in steps 40-42 are examined by central processor 6 of FIG. 2 in order to ascertain the presence of alarm conditions. If one or more alarm conditions exist, step 46 passes program control to step 47 where the alarm information is transmitted to an external device (not shown) using transceiver 33 of FIG. 2. Program control then proceeds to step 40. The flowchart repeats.

### Advantage

The distinct advantage of this invention is that charging systems can now be built that will eliminate most premature battery failures and will extend expected battery life by utilizing the optimal charge information provided by the battery. These new charging systems need not understand the type of battery that is being charged. They need only include the ability to receive and decipher charge rate messages sent by the battery in order to correctly and accurately charge the battery. These new charging systems may also contain the means to monitor alarm messages. When things like excessive internal battery pressure, low levels of electrolyte or low state of charge occur, the new charging systems can take appropriate action while notifying the operator of the problem.

What is claimed is:

1. A computer algorithm designed to be executed on a system embedded inside a vehicular battery that includes the means for calculating charge rates.

2. A computer algorithm designed to be executed on a system embedded inside a vehicular battery that includes the means for detecting internal alarm conditions.

3. A computer algorithm designed to be executed on a system embedded inside a deep-cycle battery that includes the means for calculating charge rates and detecting internal alarm conditions.

4. The computer algorithm of claim 1 wherein said means to calculate the charge rate makes use of internal battery temperature.

5. The computer algorithm of claim 1 wherein said means to calculate the charge rate makes use of internal battery pressure.

6. The computer algorithm of claim 1 wherein said means to calculate the charge rate makes use of internal battery voltage.

7. The computer algorithm of claim 1 wherein said means to calculate the charge rate makes use of the level of the liquid electrolyte of the battery.

8. The computer algorithm of claim 1 wherein said means to calculate the charge rate makes use of the specific gravity of the liquid electrolyte of the battery.

9. The computer algorithm of claim 1 wherein said means to calculate the charge rate makes use of internal battery current.

10. The computer algorithm of claim 1 wherein said means to calculate the charge rate makes use of battery specific manufacturing information.

11. The computer algorithm of claim 10 wherein said manufacturing information includes temperature based charge rate tables.

12. The computer algorithm of claim 2 wherein said means to detect an alarm condition makes use of internal battery temperature.

13. The computer algorithm of claim 2 wherein said means to detect an alarm condition makes use of internal battery pressure.

14. The computer algorithm of claim 2 wherein said means to detect an alarm condition makes use of internal battery voltage.

15. The computer algorithm of claim 2 wherein said means to detect an alarm condition makes use of the level of the liquid electrolyte.

16. The computer algorithm of claim 2 wherein said means to detect an alarm condition makes use of the specific gravity of the liquid electrolyte of the battery.

17. The computer algorithm of claim 2 wherein said means to detect an alarm condition makes use of internal battery current.

18. The computer algorithm of claim 2 wherein said means to detect an alarm condition makes use of battery specific manufacturing information.
